(19) United States
(12) Patent Application Publication
(10) Pub. No.: US 2021/0288717 A1
(43) Pub. Date: Sep. 16, 2021

(54) ILLUMINATING AND WIRELESS COMMUNICATION TRANSMITTER USING VISIBLE LIGHT

(71) Applicant: KING ABDULLAH UNIVERSITY OF SCIENCE AND TECHNOLOGY, Thuwal (SA)

(72) Inventors: Chao SHEN, Thuwal (SA); Boon Siew OOI, Thuwal (SA)

(21) Appl. No.: 17/258,183

(22) PCT Filed: Jul. 9, 2019
(86) PCT No.: PCT/IB2019/055843

§ 371 Date: Jan. 6, 2021

Related U.S. Application Data
(60) Provisional application No. 62/703,592, filed on Jul. 26, 2018.

(51) Int. Cl. H04B 10/116; H01S 5/026; H01S 5/02208; H04B 10/50

(52) U.S. Cl. CPC H04B 10/116; H04B 10/503; H01S 5/02208; H01S 5/0262

(57) ABSTRACT

An illuminating and wireless communication device includes a base; a shell attached to the base and forming a closed chamber; a laser diode located inside the closed chamber and configured to generate visible light; and a photodetector located inside the closed chamber and configured to detect incoming light. A parameter of the generated visible light is modulated to encode information.

### CROSS-REFERENCE TO RELATED APPLICATIONS

This application claims priority to U.S. Provisional Patent Application No. 62/703,592, filed on Jul. 26, 2018, entitled “AN APPARATUS OF ILLUMINATING AND WIRELESS COMMUNICATION TRANSMITTER USING VISIBLE LASER DIODES,” the disclosure of which is incorporated herein by reference in its entirety.

### BACKGROUND

### Technical Field

Embodiments of the subject matter disclosed herein generally relate to a device for illuminating and also transmitting information in a wireless manner, and more particularly, to a laser light bank device that converts electrical power into light energy for illumination and light waves for communication.

### Discussion of the Background

Light sources that generate electromagnetic radiation in the visible color regime have a variety of applications including lighting, illumination, imaging and display. Incandescent and gas discharge lamps have been widely used in the past few decades. The incandescent light bulb utilizes a tungsten filament sealed in a vacuum glass bulb, which is powered by alternating current (AC) or direct current (DC) power supply. The white light sources are widely used in both indoor and outdoor applications, including household, buildings, streets, halls etc. The technology of incandescent light bulb has, unfortunately, many drawbacks. One of them is that the conventional incandescent bulb converts over 80% of the electrical energy into thermal energy, and only less than 20% of the electrical power is utilized for generating white light. In addition, the conventional incandescent lamp routinely fails and has a lifespan of less than 1,200 hours owing to the thermal expansion and contraction of the filament element during operation.

To overcome some of the disadvantages of the conventional incandescent lamp, the fluorescent lamp and the compact fluorescent lamp (CFL) have been developed. In the CFL lamp, there are electrodes placed in a sealed tube, which is filled with a halogen gas and typically together with mercury. Once the lamp is powered on, electrons that are bound to the mercury atoms are excited to states where they will radiate ultraviolet light as they return to a lower energy level. The tube in the CFL lamp is coated with a phosphor material, which then coverts the emitted UV light into visible light. CFL lamp can be manufactured in a variety of fixtures and forms to fit in different applications, such as building structure lighting. However, the fluorescent lamp has a drawback as its poses an environmental risk due to the mercury gas in the lighting tube.

A more recent development in the illumination field has come due to the light emitting diode (LED). LED that emit white light has rapidly emerged as the solid-state lighting technology with advantages of high efficiency, long lifespan, and non-toxicity. LED lamp is based on a semiconductor light emitter, typically constructed based on a p-n junction diode emitting violet-blue-green-red light when activated using a current injection. The LED lamp relies on spontaneous emission of light. LED based white lamps have been developed based on groups III-V semiconductor materials, including GaN, InGaN, GaAs, and InP. LED lamps are now used in replacing conventional incandescent lamps and fluorescent lamps in general illumination, traffic signals, indoor lighting and street lighting.

However, the LED lamps are facing one common issue, namely the “efficiency droop,” where their power conversion efficiency reaches a peak at relative low-power density and then, rapidly drops when the operation power increases. In other words, the LED based lamp will suffer from low-efficiency for high brightness applications when the LEDs are driven by high electrical power.

As the illumination devices are facing the problems noted above, there is a similar situation in the wireless data communication industry, where a high demand of data exchanging capabilities is required, i.e., it is important to enable Internet access, live video streaming, and Internet of things (IOT) applications to many locations where it may be difficult install wireless communication capabilities. Currently, radio frequency (RF) based wireless communication technologies have been widely used. Those include Bluetooth, WiFi, wlan, cellular network, and they cover both indoor and outdoor applications. However, the RF-based wireless communications have drawbacks such as the electromagnetic interference (EMI) and security concerns. The EMI limits the RF wireless communication usage in airplanes, hospitals and other areas that are sensitive to such RF signal interference.

This is so because the RF signal usually emits in all directions and can easily transmit through walls, which is undesirable for applications requiring strong directionality and confining the signal to control the potential information leakage. Visible light communication (VLC) using LEDs has recently been proposed to address those concerns. Data communication by encoding the modulation signal in the white light bulb and detection of the data using a photodetector has been proposed and is known as Li-Fi technology. Such technology enables the illumination and data communication to take place in a same device using the same LED as the emitter. However, owing to the spontaneous emission nature of the LED lamp, the modulation bandwidth of the LED communication is limited to less than 100 MHz.

Various devices been tried to be used for both illumination and wireless data communication are now briefly discussed. U.S. Pat. No. 5,535,230, entitled “Illuminating light source device using semiconductor laser element” discloses an illuminating light source device suitable for illumination at a vibrating place or a portion where an electric lamp is hardly exchangeable for a new one. The illuminating light source device includes a semiconductor laser element for outputting a laser beam of a particular wavelength in the range from infrared rays to ultraviolet rays, a lens for diffusing the laser beam from the semiconductor laser element, and a fluorophore for converting the diffused laser beam from the diffusion lens into visible light. The illuminating light source device includes a group of semiconductor laser elements for respectively outputting laser beams of three primary colors consisting of red, green and blue, a lens for diffusing the laser beam from each of the semiconductor laser elements, and lenses for superposing the diffused laser beams from the diffusion lenses. Mercury atoms or rare earth substances are doped into the active layer of the semiconductor laser element and a second harmonic generation medium is provided on the output side of the semiconductor laser element. However, using mercury atoms poses a danger to the environment and it is undesirable.

U.S. Pat. No. 7,959,312 B2 entitled “White light emitting device and white light source module using the same” describes a white light emitting device including: a blue light emitting diode chip having a dominant wavelength of 443 to 455 nm; a red phosphor disposed around the blue light emitting diode chip, the red phosphor excited by the blue light emitting diode chip to emit red light; and a green phosphor disposed around the blue light emitting diode chip, the green phosphor excited by the blue light emitting diode chip to emit green light. Further, this reference discloses that a white LED is used and includes a resin encapsulant encapsulating the blue light emitting diode chip, where the green phosphor and the red phosphor are dispersed in the resin encapsulant. However, the efficiency of this device is limited by the efficiency droop discussed above.

U.S. Pat. No. 8,851,694 B2 entitled “Semiconductor light source apparatus” describes a semiconductor light source apparatus that includes a clad layer, a phosphor layer surrounded by the clad layer and a laser diode emitting a laser light. The phosphor layer can include a cavity having an opening for receiving the laser light, a phosphor material and a light-emitting surface of the apparatus. The laser light entering into the cavity can repeatedly reflect on an inner surface of the phosphor layer, each and every time most of the laser light entering into the phosphor layer. The laser light can be efficiently wavelength-converted by the phosphor material and the wavelength converted light can be emitted from the light-emitting surface having various shapes exposed from the clad layer. This reference also discloses guiding the light into a closed cavity or confined in a conical shape with sidewall coated with phosphors, which is difficult to implement in a practical device.

U.S. Patent Application Publication No. 2012/0106178 A1 entitled “Light emitting device, vehicle headlamp, illumination device, and laser element” describes a light-emitting section for generating fluorescence by receiving a laser beam, and a light irradiation unit for irradiating a light irradiated surface of the light emitting section with a laser beam that increases regularly in beam diameter in a direction in which the laser beam travels. The reference also discloses a light emitting device that includes one or more excitation light sources for emitting an excitation light with one concave mirror for converging the excitation light and a light emitting section for emitting fluorescence by receiving the excitation light converged by the concave mirror. However, implementing in a practical application a concave mirror and controlling the shape of the laser beam with such a mirror is cumbersome.

U.S. Patent Application Publication no. 2017/0051883 A1 entitled “Specialized integrated light source using a laser diode” describes an integrated white light source that includes a laser diode, a phosphor, a common support member to support the laser diode device and the phosphor member, a heat sink, a submount member, an output facet, a free space within a vicinity of the common support member with a non-guided characteristic capable of transmitting the laser beam from the laser diode to the phosphor member, an angle of incidence configured between the laser beam and the phosphor member, a transmissive mode characterizing the phosphor such that the laser beam is incident on an excitation surface of the phosphor member, a white light emitted from at least one emission surface of the phosphor member, and a form factor characterizing the integrated white light source.

All these devices either use elements that pose a danger to the environment, or use complicated designs that are difficult to be practically implemented in a commercial product. Therefore, there is a need to develop a better illuminating light source that is not only better at generating light for illuminating the surrounding, but also it is better in terms of data transmitting capabilities, i.e., having a better bandwidth and higher-speed.

### BRIEF SUMMARY OF THE INVENTION

According to an embodiment, there is an illuminating and wireless communication device that includes a base, a shell attached to the base and forming a closed chamber, a laser diode located inside the closed chamber and configured to generate visible light, and a photodetector located inside the closed chamber and configured to detect incoming light. A parameter of the generated visible light is modulated to encode information.

According to another embodiment, there is a method for illuminating and wireless communication, and the method includes providing an illuminating and wireless communication element, modulating an electrical current supplied to the illuminating and wireless communication element, generating modulated visible light with a laser diode, based on the modulated electrical current, and detecting incoming modulated light with a photodetector. The laser diode and the photodetector are attached to a base that is covered with a shell.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of an illuminating and wireless communication device;

FIG. 2 is a schematic diagram of another illuminating and wireless communication device;

FIG. 3A illustrates an illuminating and wireless communication device having a photodetector placed perpendicular on a laser diode and FIG. 3B illustrates an illuminating and wireless communication device having the photodetector placed away from the laser diode;

FIG. 4 illustrates a system having plural illuminating and wireless communication devices;

FIG. 5 illustrates an illuminating and wireless communication device that is surface mounted to a circuit board;

FIG. 6 illustrates an illuminating and wireless communication device having a heat sink;

FIG. 7 illustrates an illuminating and wireless communication device that is attached to a circuit board;

FIG. 8 illustrates a dome-shaped shell used to cover the illuminating and wireless communication device;

FIG. 9 illustrates a flat shell used to cover the illuminating and wireless communication device;

FIG. 10 illustrates an illuminating and wireless communication device with a dome-shaped shell;

FIGS. 11A and 11B illustrate an illuminating and wireless communication device having a temperature sensor;

FIG. 12 illustrates an illuminating and wireless communication device having a heat sink, a temperature sensor, and a flat shell; and

FIG. 13 is a flowchart of a method for generating white light and wireless communication with an illuminating and wireless communication device.

### DETAILED DESCRIPTION OF THE INVENTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of a laser light apparatus with wireless communication transmitter function that can be used indoor for illumination and wireless communication. However, the embodiments to be discussed next are not limited to a configuration that can be used for indoor only, but may be used with other configurations, for example, outdoor illumination, etc.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

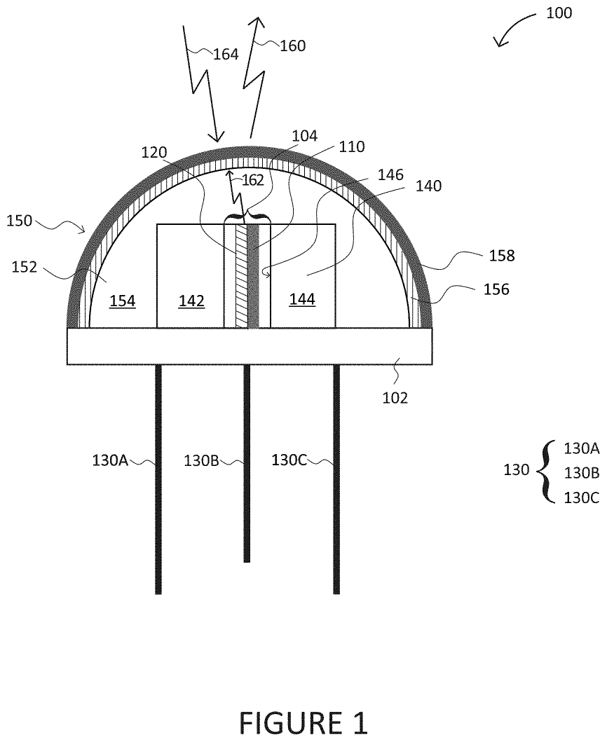

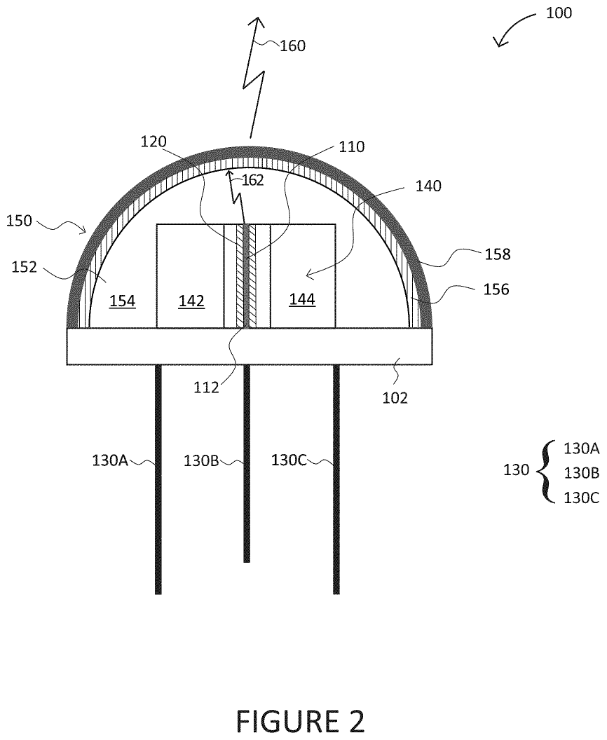

An illuminating and wireless communication device 100 is illustrated in FIG. 1 and is configured to generate visible light for illumination and also use the generated visible light for data communication. The device 100 includes a base 102, and at least one laser diode 110 and a photodetector 120 attached to the base. The photodetector is mounted in one embodiment, in parallel to the laser diode 110. The laser diode 110 may be any laser diode that is configured to emit blue light (492 to 455 nm wavelength) or violet light (455 to 390 nm wavelength). The photodetector 120 may be any device that is configured to measure light intensity. The laser diode 110 and the photodetector 120, if formed to be attached in parallel to each other as shown in FIG. 1, may be placed in a single package 104 and then this single package is attached to the base 102. The single package 104 may have the laser diode 110 effectively directly attached to the photodetector 120 as shown in FIG. 1. In one embodiment, the laser diode 110 is attached to one side of a substrate 112 while the photodetector is attached to another side of the same substrate 112, as shown in FIG. 2, and these three elements are formed as the single package 104 and attached to the base 102.

Returning to FIG. 1, plural pins 130 (the figure shows three pins 130A to 130C; however, fewer or more pins may be used), which are electrically connected to the laser diode 110 and the photodetector 120, extend through the base 102 and the pins are electrically insulated from each other if the base is made of a metal, e.g., brass or copper. However, it is possible to have the base 102 made of a ceramic or composite material, as long as the material used is a good heat dissipator.

A mounting mechanism 140 is also attached to the base 102 and configured to support the laser diode 110 and the photodetector 120. The mounting mechanism 140 may include two units 142 and 144 that surround the single package 104. In one embodiment, the two units 142 and 144 are formed as a unitary body that has a cavity 146, in which the single package 104 is placed.

A shell 150 is attached to the base 102 in such a way that the shell 150 and the base 102 define a closed chamber 152, in which the single package 104 and the mounting mechanism 140 are located. In one embodiment, the shell 150 is directly attached to the base 102 and the chamber 152 is completely sealed from the ambient. The chamber 152 may be filled with a filing material 154, which may be air, a noble gas, a gel or a solid material that are good heat conductors to conduct away the heat generated by the laser diode 110 and have a refractive index matching the refractive index of the material of the laser diode. At the same time, the filing material has to have good optical properties, i.e., to allow the light 162 emitted by the laser diode 110 to propagate to the shell 150 with minimum loss and deviation, and at the same time, to allow an incoming light 164 to arrive to the photodetector 120 with minimum loss. The filing material 154 needs to be an electrical insulator so that it will not generate a short circuit during the operation of the laser diode and the photodetector. In one application, the shell 150 does not touch the single package 104 or the mounting mechanism 140. The shell 150 may have a semi-spherical shape as shown in FIG. 1. However, other shapes may be used as discussed later.

The shell 150 may include a diffuser layer 156 that is made of a light transparent material. The material of the diffuser layer 156 is selected to be a material that diffuses or scatters light in some manner to transmit soft light. Diffused light can be obtained by reflecting light from a white surface, while more compact diffusers may use translucent material, including ground glass, teflon, holographs, opal glass, and greyed glass. The purpose of the diffuser layer 156 is to make the emitted light 160 appropriate for illumination purposes.

The diffuser layer 156 is covered with a solid color converter layer 158. The color converter layer 158 may include a solid material that is coating the diffuser layer 156. The color converter layer 158 is configured to change the blue or violet light 162 emitted by the laser diode 110 to white light, which is desired for illumination purposes. Note that in one embodiment, the laser diode 110 is a side emitting semiconductor device. In one embodiment, the shell may include, in addition to the diffuser layer, micro-gratings, blue phosphor, green phosphor, yellow phosphor, red phosphor, surface roughening layer, anti-reflection layer, or a combination of them.

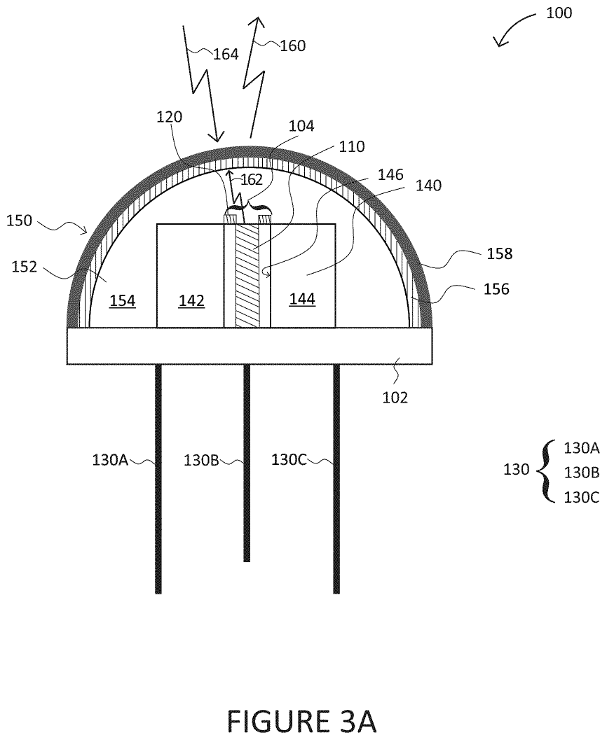

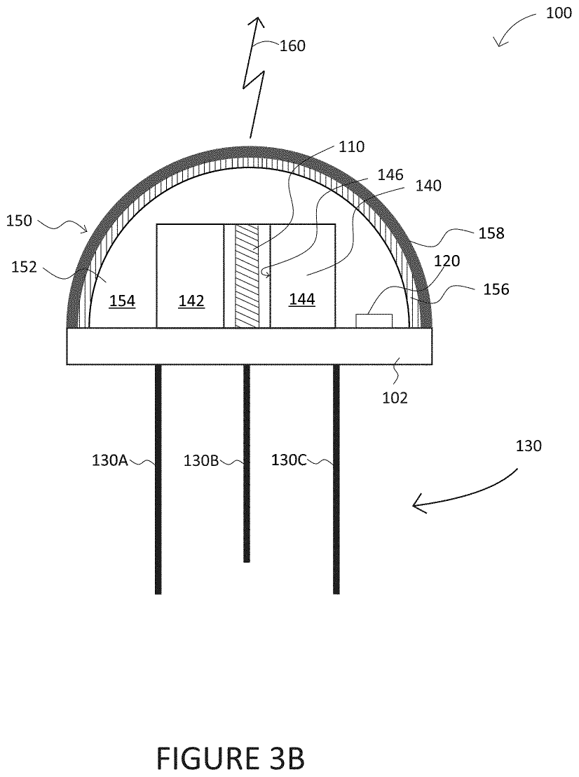

The embodiments illustrated in FIGS. 1 and 2 show the laser diode 110 and the photodetector 120 formed parallel to each other and in a single package 104. However, it is possible to have, as shown in FIG. 3A, to have the photodetector 120 formed essentially perpendicular to the laser diode 110, at the top of the laser diode. In this embodiment, the photodetector 120 is better exposed to the incoming light 164, thus achieving more accurate data communication. Further, it is possible to place the photodetector 120 anywhere inside the chamber 152, for example, on the base 102, as shown in the embodiment of FIG. 3B.

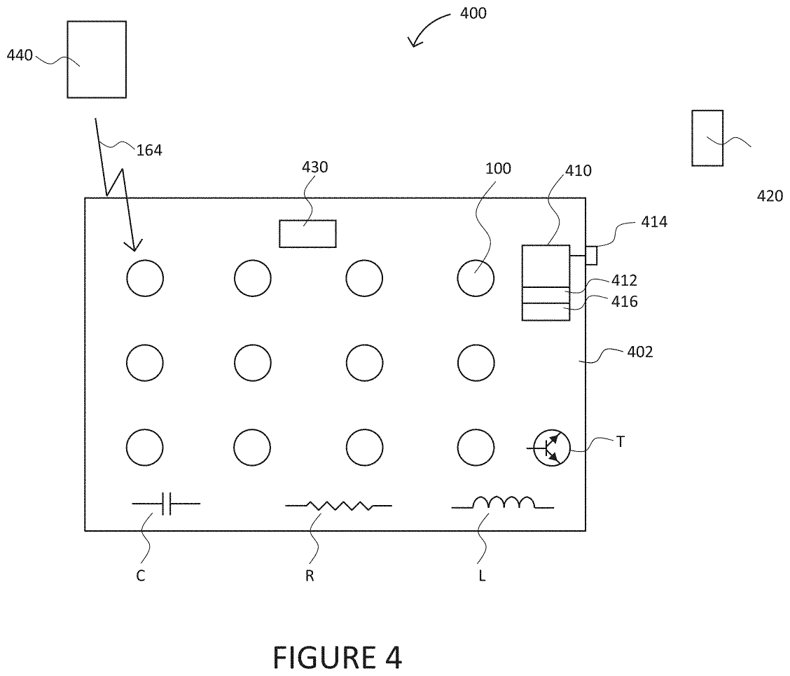

The device 100 shown in FIGS. 1 to 3B illustrate a first configuration of a white laser light element. This element 100 is suitable for plug-in mounting to a circuit board due to its electrical pins 130. A laser light power bank device 400, as shown in FIG. 4, may contain one or multiple of the basic white laser light elements 100. FIG. 4 shows the white laser light elements 100 being attached with their pins to a circuit board 402. FIG. 4 also shows, schematically, various electrical components as a capacitor C, resistor R, inductor L, transistor T being also attached to the circuit board 402. For example, a data processing device 410 may be attached to the circuit board 402 and also connected to the photodetector 120 and the laser diode 110 and include one or more of the electrical components noted above. The data processing device 410 may also include a bias-tee circuit that combines a direct current (DC) input and radio-frequency (RF) input to drive the laser diode 110 to encode data to be transmitted. In one application, both the DC and RF inputs may share the same ground. The RF modulation signal might be generated by a signal generator 412, or a field programmable gate array (FPGA) circuit, or by a pattern generator, which may not be part of the device 100. The modulation signal can be in on-off keying (OOK) or orthogonal frequency-division modulation OFDM format, and contains the data to be transmitted. The modulation signal is applied to the laser diode 110 to modulate the emitted light 162 so that the information that is desired to be transmitted to another device (e.g., mobile phone) is present into the modulated emitted light.

The data input of the signal generator/FPGA circuit might be originated from data generating device 420, for example, a server, a computer, a laptop, a cell phone, or any device that might generate data. The data exchange between the data generating device 420 and the data processing device 410 may be implemented in a wired or wireless manner. If implemented in a wired manner, the data processing device 410 is connected to a port 414 (e.g., USB, Ethernet, etc.). If implemented in a wireless manner, the data processing device 410 may include a transceiver 416 for communicating with the data generating device 420.

The data received from the data generating device 420 is then encoded by the data processing device 410 and transmitted with the laser diode 110. In one application, the intensity of the light emitted by the laser diode 110 is modulated with the signal from the data processing device to transmit the data in a wireless manner. Thus, the data processing device 410 may be in communication with a global controller 430, also located on the circuit board 402, and the global controller 430 controls the electrical power supplied to the laser diode 110 for modulating the emitted light 162. Other parameters of the light (for example frequency or phase) may be modulated for transmitting the data.

To receive data, modulated light 164 generated by a user 440 is received by the photodetector 120, through the shell 150, for each element 100 (if more than one element 100 is present). The resulting signal is sent to the data processing device 410 for demodulation and then the demodulated data may sent to the data generating device 420. Note that the data generating device 420 may be part of a data provider entity, and may be connected to the Internet through other means so that a user's device 440 (e.g., computer, cell phone, etc.) is capable to fully connect to the internet through the laser light power bank device 400 and the data generating device 420.

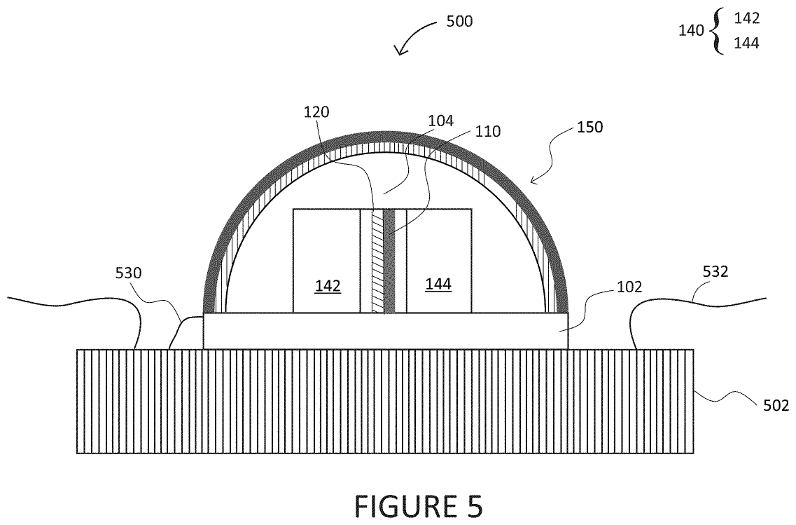

FIG. 5 shows a second configuration of the white laser light element, which is referred to herein as element 500. This element has pins 530 that are located on the side of the base 102. The pins 530 (only one shown in the figure for simplicity) can be electrically connected to a circuit board 502 by surface mounting. The pins 530 are also electrically connected to the laser diode 110 and the photodetector 120, for example, through wire bonding. Electrical connectors 532 are also connected to the circuit board 502 for providing electrical power from an external power source and/or data. More electrical connectors may be used, for example, to connect to an external driving circuit, to a computer, to a cellular phone, etc. All the other elements may be similar to those discussed in the embodiments illustrated in FIGS. 1-4.

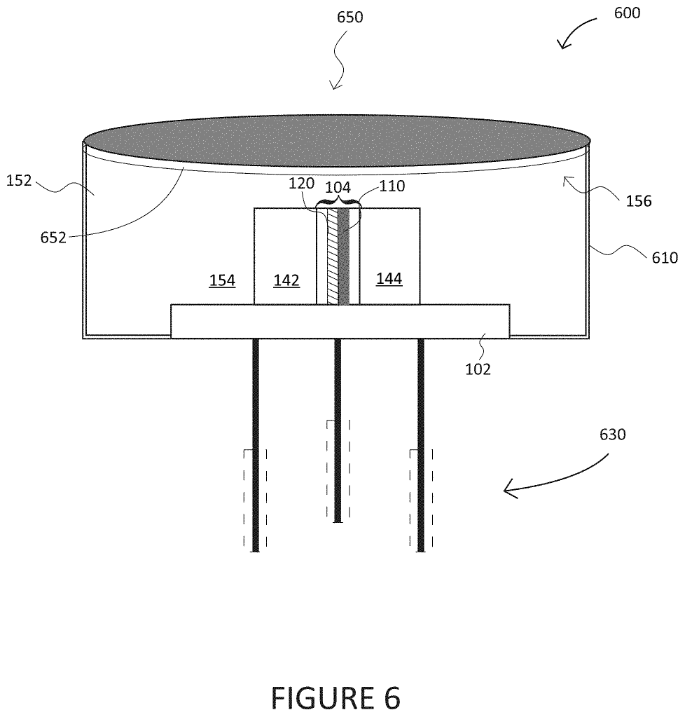

FIG. 6 shows another configuration of the white laser light element. The white laser light element 600 is configured for plug-in mounting to a circuit board trough pin holders 630 for electrical connection. The laser light power bank element 600 may include one or multiple of the basic white laser light element 100. The white laser light element 600, similar to the embodiment illustrated in FIG. 1, includes a blue-emitting or violet-emitting laser diode 110 and a photodetector 120, which is mounted in parallel to the laser diode chip on a base 102. Metal pins 630 are connected to the back side of the base 102. The pins 630 (three in this embodiment, but more are also possible) include a laser diode pin, a photodetector pin, and a ground pin. All of the pins, or at least the laser diode and the photodetector pins are insulated from the base. The laser diode pin and the photodetector pin are electrically connected to the laser diode and the photodetector chips using wire-bonding. These two elements may share the same ground and the ground terminal of both chips are wire-bonded to the ground pin. The laser diode chip emits the violet-blue optical beam from the top facet in this embodiment.

Different from the embodiment of FIG. 1, the base 102 is placed on a heatsink 610, which may be made up of copper, brass, aluminum or other very good thermal conductor materials. The heatsink 610 defines the chamber 152 and has an opening 156 at the top, where a color converter plate 650 is placed. The color converter might be a crystal or a ceramic that include YAG based materials, Group II-VI quantum dot-based materials or perovskite-based materials. The color converter plate 650 may contain one or more types of materials to convert the violet or blue light into green, yellow, orange, red, or the combination of two or more of these colors. In one embodiment, the color converter plate 650 is attached to a diffuser plate 652. Note that the shape of the color converter plate 650 in this embodiment is flat, which is different from the shape of the shell 150 in the embodiment of FIG. 1, which is dome-shaped or spherical-shaped. The filling material 154 in the embodiment of FIG. 6 may be similar to that of FIG. 1. While FIG. 6 shows the laser diode 110 and the photodetector 120 being shaped and positioned as in the embodiment of FIG. 1, one skilled in the art would understand that these two elements may be shaped and/or positioned differently, for example, as illustrated in FIGS. 3A and 3B. Other configurations may also be used.

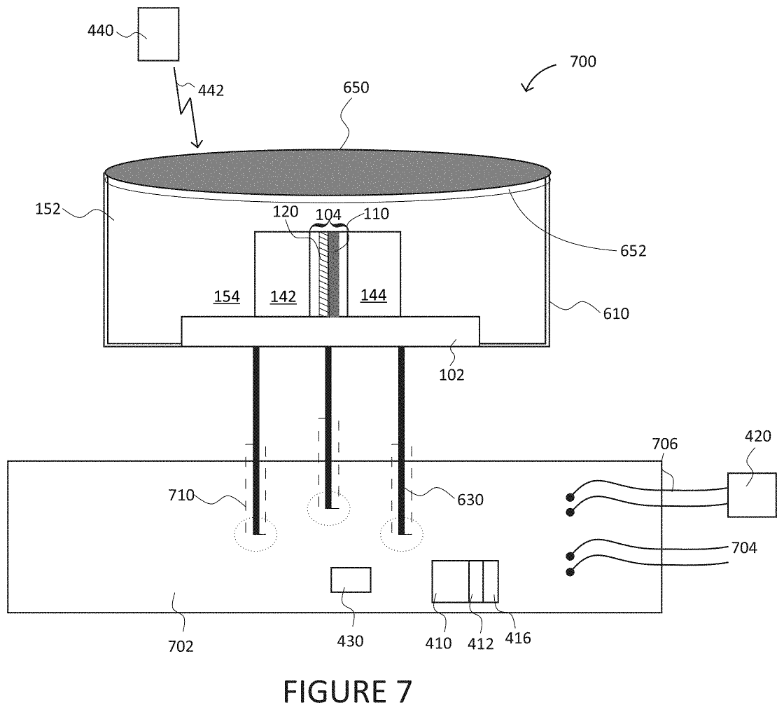

FIG. 7 shows another implementation of the white laser light element. The white laser light element 700 is configured to be mounted on a PCB driver board 702. The PCB board 702 may use base material and corresponding processing techniques that enable the operation bandwidth beyond 1 GHz, 1.5 GHz, 2 GHz and 2.5 GHz. The PCB driver board can be a 2-layer, 4-layer, 6-layer, or 8-layer PCB board with a bias-tee circuit having one or more of the following: a resistor, a capacitor, and an inductor, with DC terminal, signal terminal and laser terminal. The DC terminal will block any RF signal with frequency higher than 10 kHz, 100 kHz, or 1 MHz. The signal terminal will block any low-frequency signal with frequency lower than 10 kHz, 1 kHz, or 100 Hz. The bias-tee circuit combines the DC input and RF input to drive the laser diode. Both the DC and RF input may share the same ground. The RF modulation signal might be generated by a signal generator, or a FPGA circuit, or by a pattern generator, similar to the configuration discussed above with regard to FIG. 4. The modulation signal can be in OOK or OFDM format, and contains data to be transmitted with the element 700. The data input of the signal generator/FPGA circuit might be originated from the data source including a computer, a laptop, a cell phone, or any device that might generate data. The DC input can be in the form of continuous wave (CW) or pulse. The pulse mode can be pulse width modulation (PWM) or transistor-transistor logic (TTL) pulses. The signal input 704 and the data input 706, which are attached to the circuit board 702, can be in the form of subminiature (SMA) port, Bayonet Neill-Concelman (BNC) port, Type N port, mini-SMA port or other RF connector types. The PCB board 702 may include a plug-in device holder 710 that receives the pins 630 to make the white laser light element 700 easily replaceable by simply pulling out the current element 700 and then inserting a new element 700. In one application, the plug-in device holder may be configured to be a screw-in socket, similar to those that are used for the existing light bulbs.

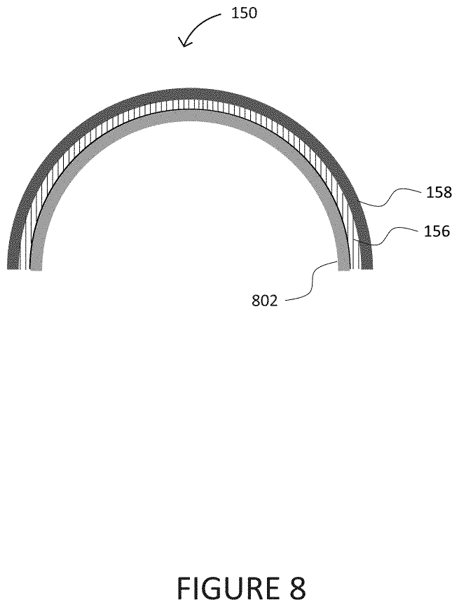

About the shell 150 used in the previous embodiments, it is noted that it can be shaped to be dome-shaped or other shapes, and it may be made of ceramic, crystal, plastic or other compound materials that is used to cover the laser diode. The dome-shape shell may contain two or more layers (as shown in FIG. 1), with at least one layer 156 serving the function of the diffuser or ball lens to shape the emitted beam 160. The dome-shaped shell 150 may also contain at least one layer of solid phosphor or color converter 158, providing the function of color conversion. As shown in FIG. 8, the shell 150 may further have one layer of anti-reflection coating 802, to reduce or eliminate the reflection from the shell 150 to the laser diode 110 or the formation of extra feedback path for the laser beam generated by the laser diode 110. A thickness of each layer can range from 0.01 mm to 10 mm. In one application, layer 802 may be a roughened surface to reduce or eliminate the reflection from the shell to the laser diode or the formation of extra feedback path for the laser beam. The thickness of this layer may range from 0.01 mm to 10 mm.

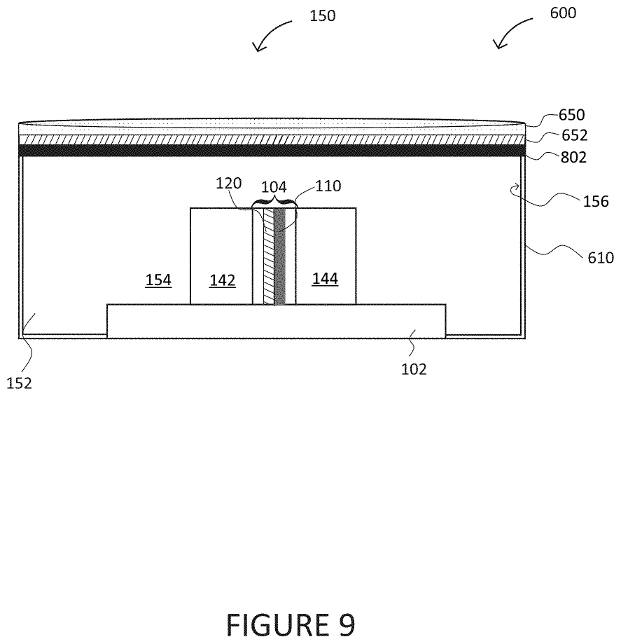

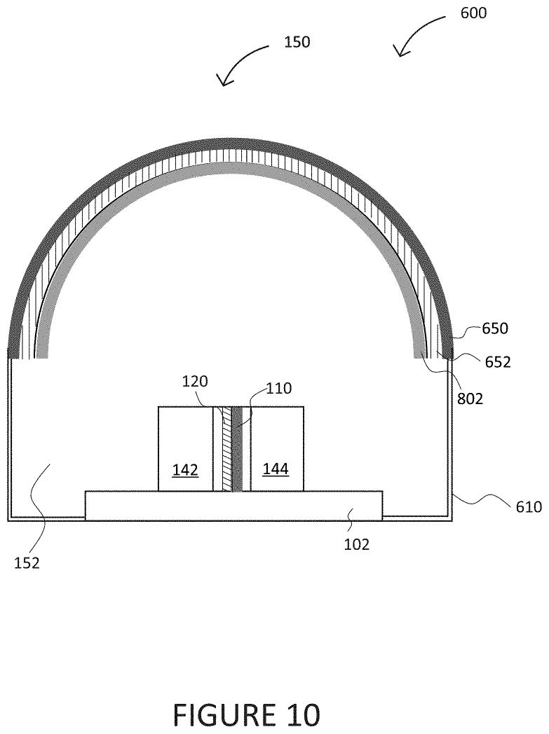

The structure of the shell 150 may be implemented, as illustrated in FIG. 9, for the configuration of the element 600 illustrated in FIG. 6. The top opening 156 of the heat sink 610 is closed with a flat shell 150 that has a diffuser layer 652, a color converter layer 650 and an anti-reflection layer/coating 802. However, as illustrated in FIG. 10, the shell 150 may also be implemented for element 600 to have a dome-shape, with the same layer structure as in the embodiment illustrated in FIG. 9.

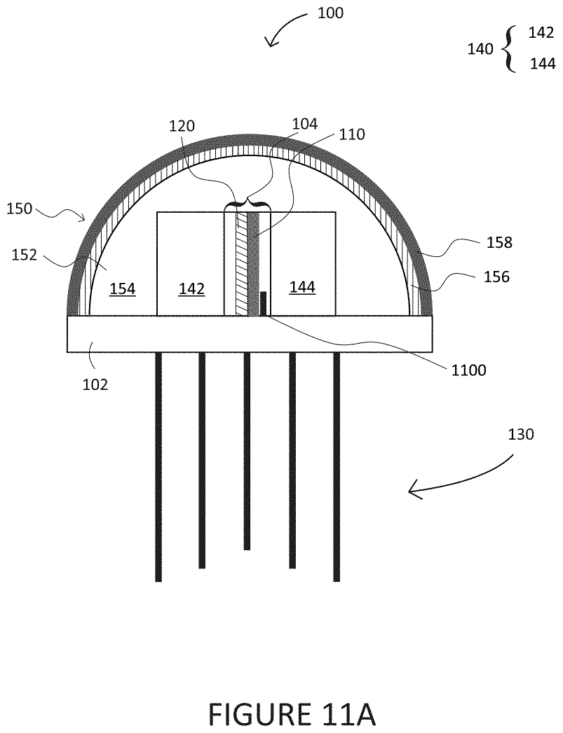

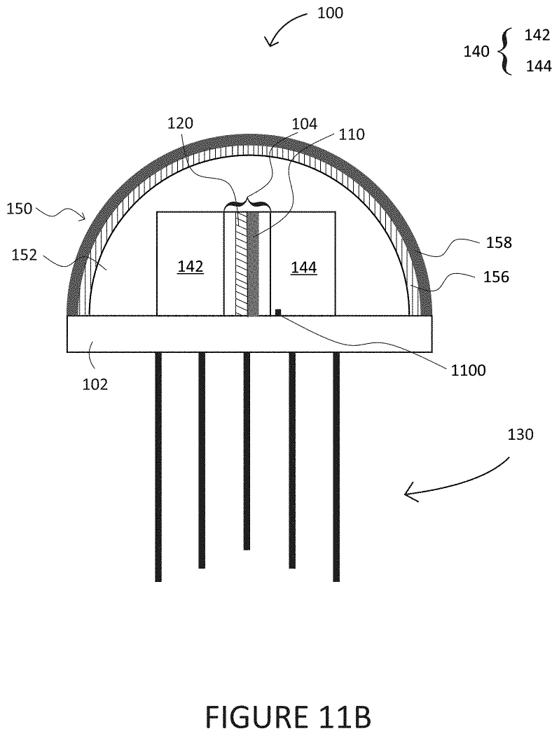

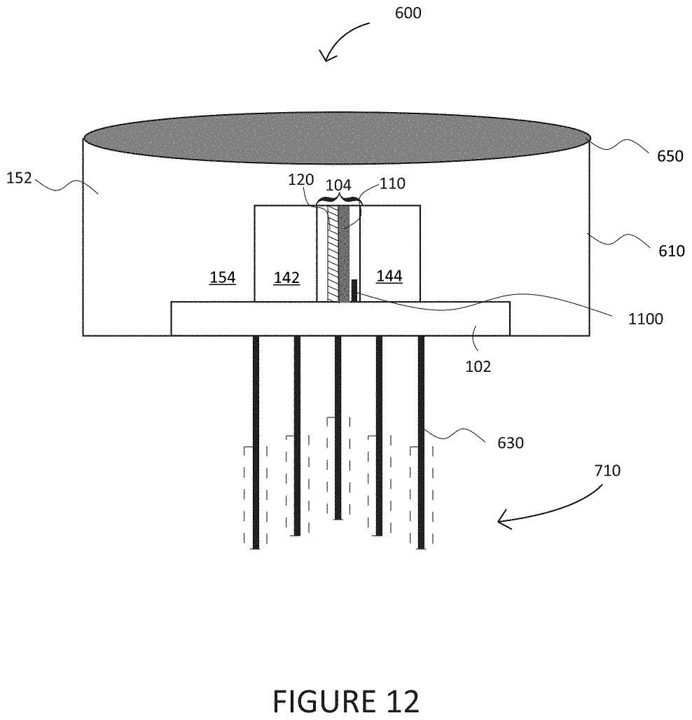

The element 100 of FIG. 1 may be modified to have a temperature sensor 1100 integrated into the single package 104 as illustrated in FIG. 11A or into the mounting mechanism 140 as illustrated in FIG. 11B. The temperature sensor is used to monitor a temperature of the single package 104 and may be implemented as a thermistor. The temperature sensor 1100 may be connected to the global controller 430 (see FIG. 4) and the temperature readings may be fed to this controller. If a temperature of the laser diode is detected to be over a given threshold, for example, 80° C., then the global controller may be programmed to switch off the power supply to the laser diode to protect it from damage. For this embodiment, the pins 130 include additional pins for transmitting the temperature signal from the temperature sensor to the global controller. The temperature signal may also be transmitted, through a port, to an outside device for displaying the temperature on a screen. The same temperature sensor 1100 may also be added to the element 600 of FIG. 600, as shown in FIG. 12. In one embodiment, the temperature sensor may be replaced with an optical power sensor, PIN photodiode, MSM photodiode, Si photodetector, etc. In another embodiment, plural sensors may be added to element 100, for example, one or more of the sensors noted above.

The element 100 may be used not only for indoor purposes (illumination and wireless communication), but also for outdoor purposes, for example, vehicle headlights that are used to communicate in a wireless manner with surrounding vehicles (e.g., cars, airplanes, drones, boats, etc.) for collision avoidance, headlight for underground mining, diving, torch light, etc. In this regard, the elements discussed above are configured to simultaneously perform the functions of light generation and data communication while also being able to illuminate a given area without performing data communication.

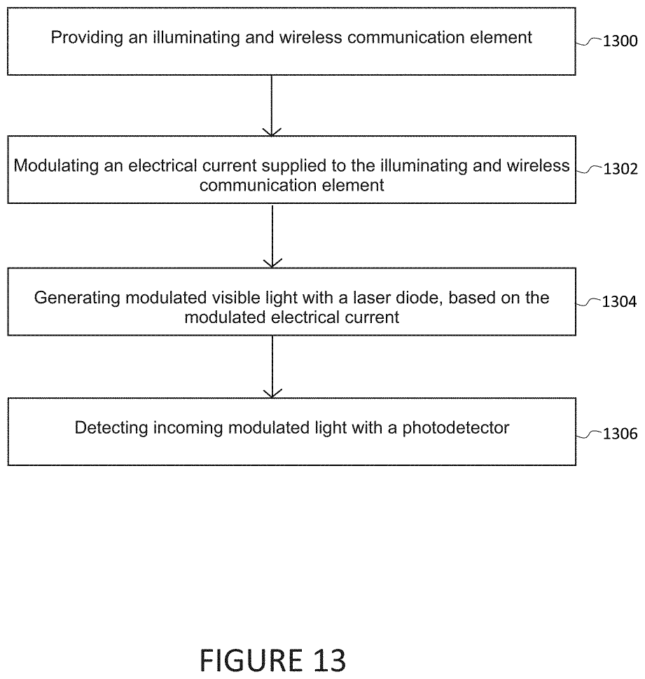

A method for illuminating and wireless communication with the element 100 is now discussed with regard to FIG. 13. The method includes a step 1300 of providing an illuminating and wireless communication element, a step 1302 of modulating 1302 an electrical current supplied to the illuminating and wireless communication element; a step 1304 of generating modulated visible light with a laser diode, based on the modulated electrical current, and a step 1306 of detecting incoming modulated light with a photodetector. The laser diode and the photodetector are attached to a base that is covered with a shell. In one application, the shell forms a closed chamber with the base, and the laser diode and the photodetector are located inside the closed chamber. The laser diode emits blue light or violet light. The laser diode is located along the photodetector. In one application, the laser diode and the photodetector are formed along a same substrate, so that the laser diode is parallel to the photodetector.

The method may further include a step of changing with a color converter layer a wavelength of the generated light to obtain white light, wherein the color converter layer is part of the shell, and/or a step of diffusing the white light with a diffuser layer, wherein the diffuser layer is part of the shell, and/or a step of measuring with a temperature sensor, which is placed inside the closed chamber, a temperature of the laser diode.

The disclosed embodiments provide a device that is capable to illuminate its surroundings with white light and also to achieve wireless communication of data through the same white light. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. An illuminating and wireless communication device comprising:
a base;
a shell attached to the base and forming a closed chamber;
a laser diode located inside the closed chamber and configured to generate visible light; and
a photodetector located inside the closed chamber and configured to detect incoming light,
wherein a parameter of the generated visible light is modulated to encode information.

2. The device of claim 1, wherein the parameter is an intensity of the generated visible light.

3. The device of claim 1, wherein the laser diode emits blue light.

4. The device of claim 1, wherein the laser diode emits violet light.

5. The device of claim 1, wherein the laser diode is located along the photodetector.

6. The device of claim 1, wherein the laser diode and the photodetector are formed along a same substrate, so that the laser diode extends in parallel to the photodetector.

7. The device of claim 1, wherein the shell includes a color converter layer that changes a wavelength of the generating light to obtain white light.

8. The device of claim 7, wherein the shell further includes a diffuser layer to diffuse the light.

9. The device of claim 8, wherein the shell further includes an anti-reflection layer.

10. The device of claim 1, further comprising:
a temperature sensor placed inside the closed chamber for monitoring a temperature of the laser diode.

11. The device of claim 1, wherein the shell is shaped as a dome.

12. The device of claim 1, wherein the shell is flat.

13. A method for illuminating and wireless communication, the method comprising:
providing an illuminating and wireless communication element;
modulating an electrical current supplied to the illuminating and wireless communication element;
generating modulated visible light with a laser diode, based on the modulated electrical current; and
detecting incoming modulated light with a photodetector,
wherein the laser diode and the photodetector are attached to a base that is covered with a shell.

14. The method of claim 13, wherein the shell forms a closed chamber with the base, and the laser diode and the photodetector are located inside the closed chamber.

15. The method of claim 13, wherein the laser diode emits blue light or violet light.

16. The method of claim 13, wherein the laser diode is located along the photodetector.

17. The method of claim 13, wherein the laser diode and the photodetector are formed along a same substrate, so that the laser diode is parallel to the photodetector.

18. The method of claim 13, further comprising:
changing with a color converter layer a wavelength of the generated light to obtain white light, wherein the color converter layer is part of the shell.

19. The method of claim 18, further comprising:
diffusing the white light with a diffuser layer, wherein the diffuser layer is part of the shell.

20. The method of claim 13, further comprising:
measuring with a temperature sensor, which is placed inside the closed chamber, a temperature of the laser diode.
